(19) United States
(12) Patent Application Publication
(10) Pub. No.: US 2020/0219871 A1
(43) Pub. Date: Jul. 9, 2020

(54) Electronic Device Including a HEMT Including a Buried Region

(71) Applicant: Semiconductor Components Industries, LLC, Phoenix, AZ (US)

(72) Inventors: Peter MOENS, Erwetegem (BE); Arno Stockman, Ronse (BE); Piet VANMEERBEEK, Sleidinge (BE); Abhishek BANERJEE, Kruibeke (BE); Frederick Johan G. DECLERCQ, Harelbeke (BE)

(73) Assignee: Semiconductor Components Industries, LLC, Phoenix, AZ (US)

(21) Appl. No.: 16/241,172

(22) Filed: Jan. 7, 2019

(51) Int. Cl. H01L 27/06; H01L 29/20; H01L 29/205; H01L 29/40; H01L 29/778

(52) U.S. Cl. CPC H01L 27/0629; H01L 29/2003; H01L 29/7787; H01L 29/402; H01L 29/205

(57) ABSTRACT

An electronic device can include a high electron mobility transistor that includes a buried region, a channel layer overlying the buried region, a gate electrode, and a drain electrode overlying the buried region. The buried region can extend toward and does not underlie the gate electrode. In a particular aspect, the electronic device can further include a p-type semiconductor member overlying the channel layer. The gate electrode can overlie the channel layer, a p-type semiconductor member overlying the channel layer. The drain electrode can overlie and contact the buried region and the p-type semiconductor member. The p-type semiconductor member can be disposed between the gate and drain electrodes. In another embodiment, a source-side buried region may be used in addition to or in place of the buried region that is coupled to the drain electrode.

### FIELD OF THE DISCLOSURE

The present disclosure relates to electronic devices, and more particularly to, electronic devices including high electron mobility transistors including buried regions.

### RELATED ART

High electron mobility transistors can be enhancement-mode transistors. One type of such transistor can include a p-type GaN gate structure. In one configuration, a barrier layer is etched and the p-type GaN is formed within the opening. Transistors with p-type GaN gate structures typically have higher dynamic on-state resistance due to plasma-induced damage from a pGaN etch in access regions. The transistor can also have relatively high on-state gate leakage as compared to depletion-mode high electron mobility transistors. When the p-type GaN includes Mg, some Mg may diffuse into the GaN channel layer and increase on-state resistance.

Alternatively, an enhancement-mode transistor can be formed with a dielectric layer as part of the gate structure. A barrier layer can be etched and cause plasma damage that generates interface states or traps between the etched (plasma damaged) semiconductor surface and a subsequently-deposited gate dielectric. This can cause high hysteresis, threshold voltage instability, and relatively higher gate leakage and relatively lower gate voltage overdrive as compared to a depletion-mode high electronic mobility transistor. Further improvement of enhancement-mode high electron mobility transistors without the previously mentioned adverse complications is desired.

### BRIEF DESCRIPTION OF THE DRAWINGS

Embodiments are illustrated by way of example and are not limited in the accompanying figures.

FIG. 1 includes an illustration of a cross-sectional view of a portion of a workpiece including a substrate, superlattice structure, a buffer layer, and a drain-side buried region.

FIG. 2 includes an illustration of a cross-sectional view of the workpiece of FIG. 1 after forming a channel layer, barrier layer, and a gate electrode.

FIG. 3 includes an illustration of a cross-sectional view of the workpiece of FIG. 2 after substantially completing formation of an enhancement-mode HEMT structure in accordance with an embodiment.

FIG. 4 includes a plot of minimum lateral spacing between the buried region and the gate electrode versus the rated voltage of the HEMT.

FIG. 5 includes an illustration of a cross-sectional view of a HEMT structure that further includes a source-side buried region in accordance with another embodiment.

FIG. 6 includes an illustration of a cross-sectional view of the HEMT structure of FIG. 5 further including a conductive region in accordance with another embodiment.

FIG. 7 includes an illustration of a cross-sectional view of the HEMT structure of FIG. 5 further including a conductive region in accordance with another embodiment.

FIG. 8 includes an illustration of a cross-sectional view of the HEMT structure of FIG. 5 with a different source-side buried region having thicker and thinner portions in according with another embodiment.

FIG. 9 includes an illustration of a cross-sectional view of a reverse blocking enhancement-mode HEMT in accordance with another embodiment.

FIG. 10 includes an illustration of a cross-sectional view of the HEMT structure having a source-side buried region coupled to a back barrier electrode in accordance with another embodiment.

FIG. 11 includes an illustration of a cross-sectional view of a HEMT structure including buried regions, where the HEMT is configured as a bidirectional transistor in accordance with a further embodiment.

Skilled artisans appreciate that elements in the figures are illustrated for simplicity and clarity and have not necessarily been drawn to scale. For example, the dimensions of some of the elements in the figures may be exaggerated relative to other elements to help to improve understanding of embodiments of the invention.

### DETAILED DESCRIPTION

The following description in combination with the figures is provided to assist in understanding the teachings disclosed herein. The following discussion will focus on specific implementations and embodiments of the teachings. This focus is provided to assist in describing the teachings and should not be interpreted as a limitation on the scope or applicability of the teachings. However, other embodiments can be used based on the teachings as disclosed in this application.

A III-V material is intended to mean a material that includes at least one Group 13 and at least one Group 15 element. A III-N material is intended to mean a semiconductor material that includes at least one Group 13 element and nitrogen.

The term “base semiconductor material” is intended to mean a semiconductor material without regard to the presence, absence, or type of an aliovalent dopant with respect to the semiconductor material. For example, unintentionally doped GaN, p-type doped GaN, and n-type doped GaN all have GaN as the base semiconductor material. GaN and AlₐGa₍₁₋ₐ₎N, where 0.1<a≤1, are different base semiconductor materials.

With respect directions and dimensions, the term “lateral” and its variants refer to a direction or dimension along a primary surface of a workpiece or a plane parallel to the primary surface. The primary surface may correspond to a surface of a layer within the workpiece. Two components may lie at different elevations and separated by a distance in an x-axis, a y-axis or both the x- and y-axes, where the x- and y-axes are perpendicular to each other. Lateral dimensions do not consider vertical, or z-axis, offsets.

The term “normal operation” and “normal operating state” refer to conditions under which an electronic component or device is designed to operate. The conditions may be obtained from a data sheet or other information regarding voltages, currents, capacitance, resistance, or other electrical parameters. Thus, normal operation does not include operating an electrical component or device well beyond its design limits.

The terms “comprises,” “comprising,” “includes,” “including,” “has,” “having” or any other variation thereof, are intended to cover a non-exclusive inclusion. For example, a method, article, or apparatus that comprises a list of features is not necessarily limited only to those features but may include other features not expressly listed or inherent to such method, article, or apparatus. Further, unless expressly stated to the contrary, “or” refers to an inclusive-or and not to an exclusive-or. For example, a condition A or B is satisfied by any one of the following: A is true (or present) and B is false (or not present), A is false (or not present) and B is true (or present), and both A and B are true (or present).

Also, the use of “a” or “an” is employed to describe elements and components described herein. This is done merely for convenience and to give a general sense of the scope of the invention. This description should be read to include one, at least one, or the singular as also including the plural, or vice versa, unless it is clear that it is meant otherwise. For example, when a single item is described herein, more than one item may be used in place of a single item. Similarly, where more than one item is described herein, a single item may be substituted for that more than one item.

The use of the word “about”, “approximately”, or “substantially” is intended to mean that a value of a parameter is close to a stated value or position. However, minor differences may prevent the values or positions from being exactly as stated. Thus, differences of up to ten percent (10%) for the value are reasonable differences from the ideal goal of exactly as described.

Group numbers corresponding to columns within the Periodic Table of Elements based on the IUPAC Periodic Table of Elements, version dated Nov. 28, 2016.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and may be found in textbooks and other sources within the semiconductor and electronic arts.

An enhancement-mode high electron mobility transistor (HEMT) can include a buried region that has better performance than an enhancement-mode HEMT without any buried region. In some embodiments, a diode lies between the buried region and a two dimension electron gas (2DEG), where the buried region is the anode of the diode. In an off-state, the diode can be forward biased, and the buried region can inject holes into the channel layer to recombine with trapped electrons and reduce or eliminate dynamic on-state resistance. The lateral spacing between a drain-side buried region can be selected so that holes can be injected along all of the channel layer that is laterally between the gate electrode and the drain electrode. Further, when in an off-state, the drain-side buried region can lower the maximum electrical field at the drain edge in the drain region. A drain-side field plate may or may not be used with the drain-side buried region, and the drain-side buried region or combination of a drain-side field plate and a drain-side buried region can be optimized and engineered to achieve a desired electrical field. In an on-state, a buried region at a positive potential with respect to the 2DEG can increase the electron density within the 2DEG and reduce on-state resistance (Rdson).

In another embodiment, a source-side buried region can be coupled to a source electrode or a back barrier electrode. A relatively thicker portion of the source-side buried region under a gate electrode can help with dual depletion of the channel of the HEMT, and a relatively thinner portion that is relatively farther away from the 2DEG to increase the 2DEG electron density. The thicker portion can be replaced by another relative thinner portion (the source-side buried region may have a substantially uniform thickness similar to the thinner portion) that can be beneficial for Third Quadrant (3Q) operation. A portion of the source-side buried region may extend beyond the gate electrode to help shield the 2DEG from the substrate voltage.

In an aspect, an electronic device can include a high electron mobility transistor that includes a buried region, a channel layer overlying the buried region, a gate electrode, and a drain electrode overlying the buried region. The buried region can extend toward and does not underlie the gate electrode.

In a further aspect, an electronic device can include a high electron mobility transistor that includes a buried region, a channel layer overlying the buried region, a gate electrode overlying the channel layer, a p-type semiconductor member overlying the channel layer, and a drain electrode that overlies and contacts the buried region and the p-type semiconductor member. The p-type semiconductor member can be disposed between the gate and drain electrodes.

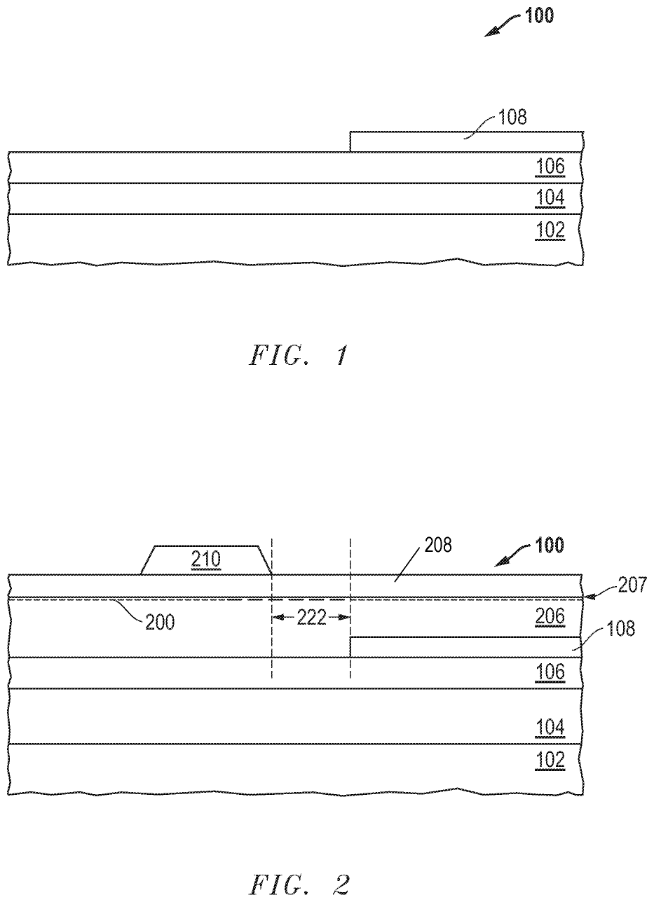

FIG. 1 includes a cross-sectional view of a portion of a workpiece 100 can include a substrate 102, a Super Lattice Structure (SLS) 104, a buffer layer 106, and a buried region 108. The substrate 102 can include silicon, sapphire (monocrystalline Al₂O₃), silicon carbide (SiC), aluminum nitride (AlN), gallium oxide (Ga₂O₃), spinel (MgAl₂O₄), another suitable substantially monocrystalline material, or the like. The selection of the particular material and crystal orientation along the primary surface can be selected depending upon the composition of the overlying semiconductor layers.

The SLS 104 can include a III-V semiconductor base material, such as a III-N semiconductor base material. In an embodiment, the SLS can include AlₓGa₍₁₋ₓ₎N, where 0≤x≤1. The composition of the SLS 104 may depend on the composition of a subsequently-formed channel layer and the designed operating voltage of the HEMT. The composition of the SLS 104 can be changed as a function of thickness, such that the SLS 104 has a relatively greater aluminum content closer to the substrate 102 and relatively greater gallium content closer to the channel layer. In a particular embodiment, the cation (metal atoms) content in the SLS 104 near the substrate 102 can be 10 atomic % to 100 atomic % Al with the remainder Ga, and the cation content in the SLS 104 near the channel layer can be 0 atomic % to 50 atomic % Al with the remainder Ga. In another embodiment, the SLS 104 can include a plurality of films. The SLS 104 can have a thickness in a range from 0.5 micron to 10 microns.

The buffer layer 106 can include a III-V semiconductor base material, such as a III-N semiconductor base material. In an embodiment, the buffer layer 106 can include AlₐGa₍₁₋ₐ₎N, where 0≤a≤0.1. In a particular embodiment, the buffer layer includes GaN (a=0). The buffer layer 106 can include electron acceptors, and the acceptors can be carbon. In an embodiment, carbon can come from a source gas (e.g., Ga(CH₃)₃) when metalorganic chemical vapor deposition (MOCVD) is used to form the buffer layer 106. The dopant concentration can be at least 1×10¹⁷ atoms/cm³. In an embodiment, the dopant concentration may be at most 1×10²¹ atoms/cm³. The buffer layer 106 can have a thickness in a range from 50 nm to 500 nm.

The buried region 108 can include a p-type semiconductor material that includes a III-V semiconductor base material, such as a III-N semiconductor base material. The buried region 108 can be initially formed as a III-V semiconductor layer over all of the buffer layer 106. The III-V semiconductor layer can include AlₓGa₍₁₋ₓ₎N, where 0≤x≤0.3. In a particular embodiment, the III-V semiconductor layer is a GaN layer (x=0). The p-type dopant can include Mg, Ca, Cd, C, or the like. The p-type dopant can be incorporated as the III-V semiconductor layer of the buried region 108 is grown, the III-V semiconductor layer can be doped after it is grown. The p-type dopant concentration can be at least 1×10¹⁶, atoms/cm³ at least 1×10¹⁷, or atoms/cm³ at least 1×10¹⁸ atoms/cm³. In an embodiment, the dopant concentration may be at most 1×10²¹ atoms/cm³. In an embodiment, the III-V semiconductor layer can have a thickness in a range from 5 nm to 500 nm. The III-V semiconductor layer can be patterned to form the buried region 108. The positional relationship between the buried region 108 and other subsequently-formed components of the HEMT structure will be described later in this specification.

In an embodiment, the SLS 104, the buffer layer 106, and the III-V semiconductor layer for the buried region 108 can be formed without exposing the workpiece to air between forming any one or more of the layers. In an embodiment, each of the SLS 104, the buffer layer 106, and the III-V semiconductor layer can be epitaxially grown from its corresponding underlying layer. In a particular embodiment, the SLS 104, the buffer layer 106, and the III-V semiconductor layer can be formed using metalorganic chemical vapor deposition (MOCVD), molecular beam epitaxy (MBE), or the like.

FIG. 2 includes the workpiece after forming a channel layer 206 having a primary surface 207, a barrier layer 208, and a gate electrode 210. The channel layer 206 can include a III-V semiconductor base material, such as a III-N semiconductor base material. In an embodiment, the buffer layer 106 and the channel layer 206 can have the same base semiconductor material. In an embodiment, the channel layer 206 can include AlₓGa₍₁₋ₓ₎N, where 0≤x≤0.1. In a particular embodiment, the channel layer 206 is a GaN layer (x=0). The channel layer 206 may be unintentionally doped or doped with an electron donor (n-type) dopant or an electron acceptor (p-type) dopant. A 2DEG 200 is formed near the interface of the channel layer 206 and the barrier layer 208 and is responsible for high mobility and lower resistivity of the transistor structure when in the on-state. The buried layer 108 can affect the electron density within the 2DEG 200. Any reduction of the electron density within the 2DEG 200 will increase the on-resistance of the transistor. In an embodiment, the concentration of acceptors (when the carriers are electrons) or donors (when the carriers are holes) in the channel layer 206 may be kept as low as reasonably possible. Thus, the channel layer 206 has a significantly lower dopant concentration (e.g., C content) as compared to the buffer layer 106.

In a particular embodiment, the lowest electron trap concentration in the channel layer 206 is desired but may be limited by growth or deposition conditions and purity of the precursors. Thus, some carbon can become incorporated as the channel layer 206 is grown, and, such carbon can result in unintentional doping. The carbon content may be controlled by controlling the deposition conditions, such as the deposition temperature and flow rates. In an embodiment, the channel layer 206 has a carrier impurity concentration that is greater than 0 and less than 1×10¹⁷ atoms/cm³. In a further embodiment, the carrier impurity concentration is in a range from 1×10¹³ atoms/cm³ to 1×10¹⁷.

The thickness of the channel layer 206 is selected so that depth of the buried region 108 from the primary surface 207 is sufficient to not deplete a 2DEG that lays along an interface between the channel layer 206 and the barrier layer 208. Further, the thickness of the channel layer 206 can be selected so that the primary surface 207 is planar over the workpiece, including areas where the buried region 108 are not present. If the channel layer 206 is too thick, the effectiveness of the buried region 108 and buffer layer 106 may be substantially reduced. As used herein, the thickness of the channel layer 206 corresponds to the thickness spaced apart from the buried region 108, unless explicated stated to the contrary. Referring to FIG. 2, the thickness of the channel layer 206 corresponds to the distance between the buffer layer 106 and the barrier layer 208. In an embodiment, the channel layer 206 can have a thickness of at least 20 nm, and in another embodiment, the channel layer 206 can have a thickness of at most 4000 nm. In a particular embodiment, the thickness of the channel layer 206 is in a range from 50 nm to 500 nm.

The barrier layer 208 can include a III-V semiconductor base material, such as a III-N semiconductor base material. In a particular embodiment, the barrier layer can include Al_{y}In_{z}Ga_{(1-y-z)}N, wherein 0<y≤1 and 0≤z≤0.3. The barrier layer 208 can include a single film or a plurality of films. When the barrier layer 208 includes a plurality of films, the aluminum content can remain substantially the same or increase as distance from the channel layer 206 increases. As the aluminum content in the barrier layer 208 increases, the thickness of the barrier layer 208 may be relatively thinner. In an embodiment, the barrier layer 208 has a thickness of at least 5 nm, and in another embodiment, the barrier layer 208 has a thickness of at most 150 nm. In a particular embodiment, the barrier layer 208 has a thickness in a range from 10 nm to 90 nm.

The gate electrode 210 can have any of the compositions, thicknesses, and formation techniques as previously discussed with respect to the buried region 108. The gate electrode 210 can have the same or different composition as compared to the buried region 108, the gate electrode 210 can have the same or different thickness as compared to the buried region 108, and the gate electrode 210 can be formed the same or different using the same technique as compared to the buried region 108. In an embodiment, the gate electrode 210 can be thicker as compared to the buried region 108.

In an embodiment, the channel layer 206, the barrier layer 108, and the III-V semiconductor layer for the gate electrode 210 can be formed without exposing the workpiece to air between forming any one or more of the layers. In an embodiment, each of the channel layer 206, the barrier layer 208, and the III-V semiconductor layer can be epitaxially grown from its corresponding underlying layer. In a particular embodiment, the channel layer 206, the barrier layer 208, and the III-V semiconductor layer can be formed using MOCVD, MBE, or the like.

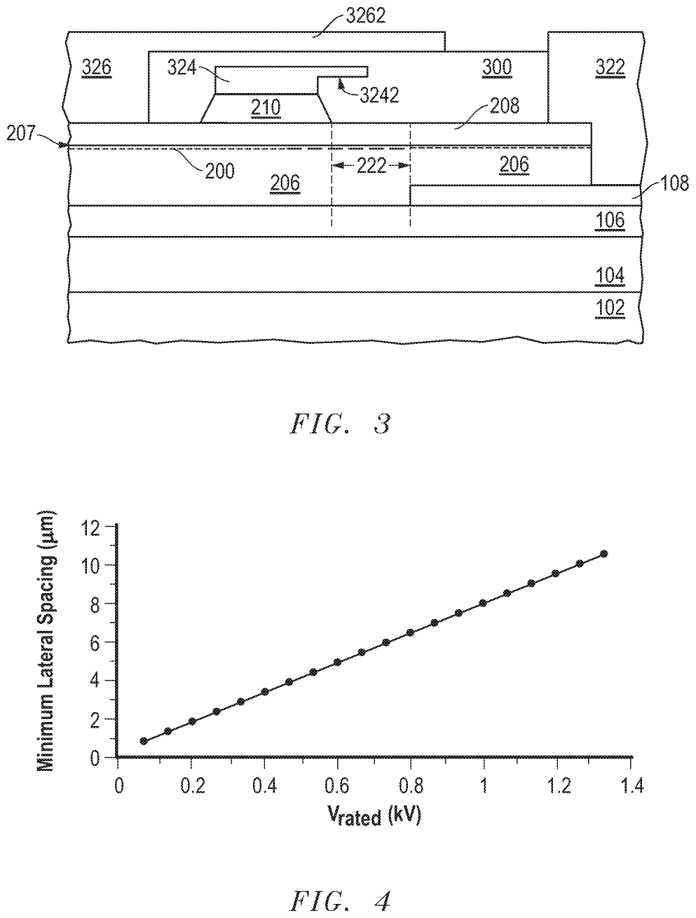

The presence of the buried region 108 and gate electrode 210 allows the areal density of electrons within the 2DEG 200 to be lower at an area laterally between and near the edges of the buried region 108 and the gate electrode 210, as compared to other areas of the 2DEG 200. The buried region 108 and gate electrode 210 are laterally spaced apart from each other by a lateral spacing 222. A minimum suggested value for the lateral spacing 222 depends on the voltage that the HEMT structure is to support. Considerations for the value of the lateral spacing 222 is address in more detail with respect to FIG. 4.

FIG. 3 illustrates the HEMT after forming an interlevel dielectric (ILD) layer 300, a drain electrode 322, a gate interconnect 324, and a source electrode 326. The illustration in FIG. 3 is a simplified version of the ILD layer 300, the drain electrode 322, the gate interconnect 324, and the source electrode 326. A more accurate depiction and description can be found in U.S. Pat. No. 9,673,311, which is incorporated for its description of the insulating and conductive layers used to form ILD layers, electrodes, interconnects, and field plates (also called shielding plates). The discussion below is focused more on the drain electrode 322 with respect to the buried region 108.

A portion of a contact opening for the drain electrode 322 extends through the ILD layer 300, the barrier layer 208, and the channel layer 206. In an embodiment, the buried region 108 lies along the portion of the contact opening for the drain electrode 322. A portion of the drain electrode 322 may be formed at this time. Other portions of the contact opening and the conductive layers for the drain electrode 322 can be formed when forming contact openings and conductive layers for the source electrode 326 and gate interconnect 324. Uppermost levels of the source electrode 326 and the gate interconnect 324 can include field plates 3262 and 3242. The field plate 3262 extends over and beyond the gate electrode 210 toward the drain electrode 322, and the field plate 3242 extends beyond the gate electrode 210 toward the drain electrode 322. As illustrated in FIG. 3, the field plate 3262 extends laterally further toward the drain electrode 322 as compared to the field plate 3242. A portion of the field plate 3262 extends over the buried region 108. In another embodiment, the field plates 3242 and 3262 may extend different lateral distances that those described. Further, more or fewer field plates may be used, as needed or desired.

The buried region 108 and the gate electrode 210 are separated by the lateral spacing 222. The lateral spacing 222 may a lower value because, inside the semiconductor material. the critical electric fields that can be sustained are higher than at the interfaces (e.g., the interface between the barrier layer 208 and the dielectric layer 300). This is due to the better crystalline quality inside the semiconductor material. Due to the higher critical fields, a lower distance is required to sustain the same voltage. FIG. 4 includes a plot of voltage as a function of minimum lateral spacing between the buried region 108 and the gate electrode 210. Typically, for a lateral HEMT transistor, the rated voltage (Vrated) is ⅔ of the breakdown voltage (Vbd). In order to support a given Vrated, the lateral spacing can be:

y≥7.5(x)+0.3

where:

y is the lateral spacing, in units of microns, and

x is the Vrated, in units of kV.

Features of the HEMT structure are noteworthy. Because the buried region 108 is away from the 2DEG, and thus, does not significantly interfere with the field plates 3242 and 3262 that help to deplete the 2DEG 200 when the HEMT is in the off-state. The buried region 108 is sufficiently deep so it does not deplete the 2DEG 200 by a rise in the energy of the conduction band. When in the off-state, a diode formed along an interface of the buried region 108 and the channel layer 206 is forward biased, and the buried region 108 can inject holes into the channel layer 206. These holes can recombine with the trapped electrons within the channel layer 206, and hence dynamic on-state resistance is substantially reduced or elimination. Because the buried region 108 extends significantly towards the gate electrode 210, holes can be substantially injected along all of the lateral gap between the gate electrode 210 and the drain electrode 322. In the off-state, the buried region 108 can act as a field plate and lower the maximum electrical field at the edge of the drain electrode 322 and in the drift region along the 2DEG 200 laterally between the gate electrode 210 and the drain electrode 322. When the HEMT is in an on-state, the buried region 108 can be at a positive potential with respect to the 2DEG 200 and helps to increase the electron density within the 2DEG 200 and lower on Rdson.

Other embodiments can be used. In an embodiment (not illustrated), an additional layer similar to the buffer layer 106 may be formed after forming the buried region 108 and before forming the channel layer 206. The additional layer can have any of the compositions, thicknesses, and be formed using any of the techniques used in forming the buffer layer 106. The additional layer can help to spread holes to provide a larger hole concentration. In an embodiment, the additional layer can have a thickness in a range from 10 nm to 500 nm.

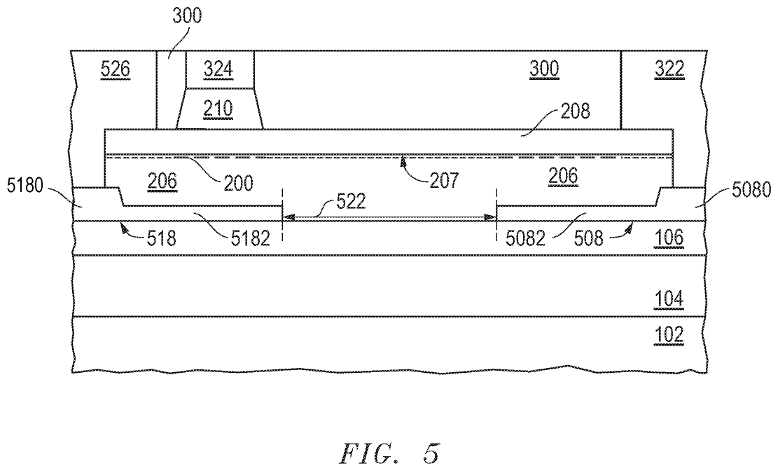

In a further embodiment, a buried region may be used on the source side of the HEMT. FIG. 5 includes an illustration of such an embodiment that includes a drain-side buried region 508 and a source-side buried region 518. The source-side buried region 518 can help to lift the energy of the conduction band and help increase the threshold voltage. The source-side buried region 518 may obviate the need for shielding plates overlying the 2DEG 200, as will be described later in this specification. The buried regions 508 and 518 are spaced apart and can have a lateral spacing 522 having any of the values as previously described with respect to the lateral spacing 222.

The drain-side buried region 508 is similar to the buried region 208 having a relatively thinner portion 5082 and further includes a relatively thicker portion 5080 under the drain electrode 322. The source-side buried region 518 is a mirror image of the drain-side buried region 508 and has a relatively thicker portion 5180 under the source electrode 526 and a relatively thinner portion 5182 extending from the thicker portion 5180 toward the drain-side buried region 508. The relatively thicker portions of the buried regions 508 and 518 may allow for more process margin when forming the drain and source electrodes 322 and 526 to reduce the likelihood of etching through the buried regions 508 and 518 and reaching the buffer layer 106. The thinner portions 5082 and 5182 of the buried regions 508 and 518 may have thicknesses as previously described with respect to the buried region 108, and the thicker portions 5080 and 5180 may have thicknesses in a range from 1.5 to 10 times thicker than the thinner portions 5082 and 5182. In a particular embodiment, the thicknesses of the thicker portions 5080 and 5180 can be in a range from 50 nm to 900 nm thick. In another embodiment, the source-side buried region 518 may be used without the drain-side buried region 508.

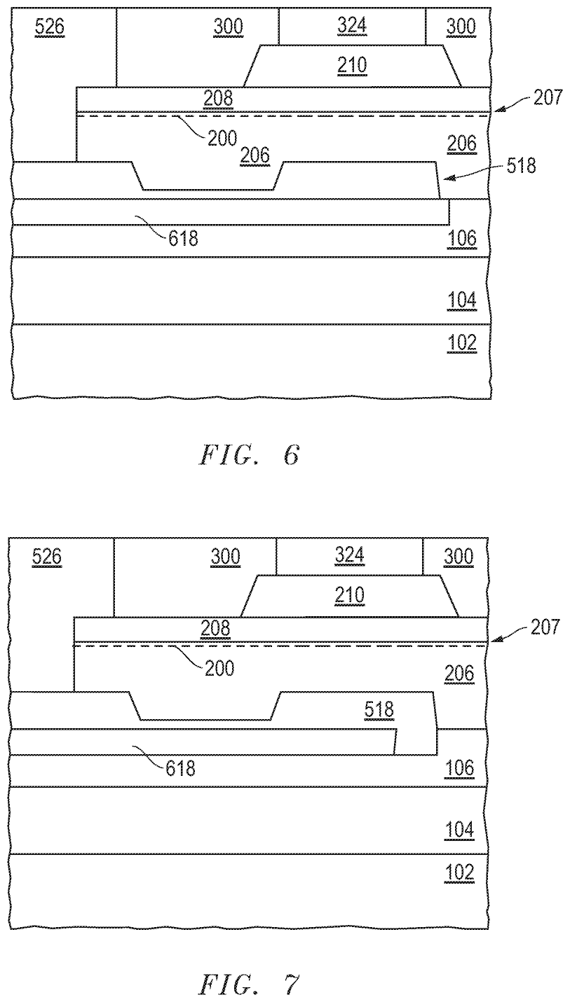

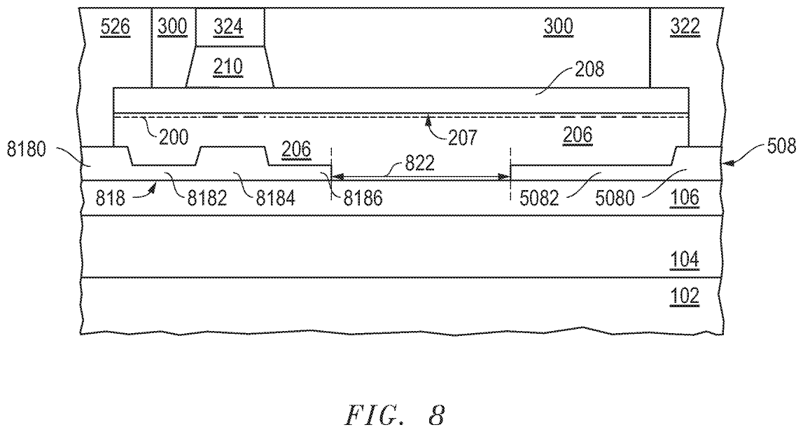

In an embodiment, the source-side buried region 518 can have a resistivity higher than desired. Accordingly, in another embodiment, a conductive region 618 may underlie all of the source-side buried region 518, as illustrated in FIG. 6, or may underlie of portion of the source-side buried region 518, as illustrated in FIG. 7. The conductive region 618 can help to reduce the voltage difference along a length of the source-side buried region 518. In an embodiment, the conductive region 618 can provide a positive charge and include AlⱼGa₍₁₋ⱼ₎N, where 0<j≤1. In such an embodiment, the conductive region 618 may extend along all of the buried region 518.

In a further embodiment, the conductive region 618 can include heavily n-type doped AlₖGa₍₁₋ₖ₎N, where 0≤k≤1. The doping concentration of the n-type doped AlₖGa₍₁₋ₖ₎N can be any of the concentrations previously described with respect to the buried region 108. In a particular embodiment, AlₖGa₍₁₋ₖ₎N can be GaN and have a higher dopant concentration as compared to the p-type dopant concentration of the source-side buried region 518. The n-type doped AlₖGa₍₁₋ₖ₎N may be used along all of the buried region 518 as illustrated in FIG. 6. In another embodiment, a portion of the buried region 518 may extend along a lateral end of the conductive region 618, as illustrated in FIG. 7. The portion of the buried region 518 can form a blocking diode that reduces leakage current between the source and drain of the HEMT structure.

The source electrode 526 in FIGS. 5 to 7 can have a structure similar to the drain electrode 322. A portion of the source electrode 526 can overlie and contact the upper surface of the barrier layer 208, and another portion of the source electrode 526 can contact an underlying region. For the embodiment illustrated in FIG. 5, the drain and source electrodes 322 and 526 can be formed using the same process sequence. With respect to the embodiments illustrated in FIGS. 6 and 7, a portion of the contact opening can be extended to make an ohmic contact with the conductive region 618.

FIG. 8 includes a cross-sectional view of another embodiment in which a source-side buried region 818 that includes portions 8180, 8182, 8184, and 8186. The portions 8180 and 8184 are relatively thicker than the portions 8182 and 8186 and provides a local back barrier under the gate electrode 210, resulting in dual depletion of the channel. The local back barrier can be connected to the source electrode 526 by a stepped profile of the buried region 818. The portion 8182 is relatively thinner than the portion 8184 and extends from the portion 8184 toward the source electrode 526. As compared to the portion 8184, the portion 8182 is relatively farther away from the 2DEG 200 in the source-gate access region to increase the 2DEG electron density. The portion 8186 is relatively thinner than the portion 8184 and extends from the portion 8184 toward the drain electrode 322. The portion 8186 can help to screen the voltage of the substrate 102 from the 2DEG 200.

The portions 8182 and 8186 may have thicknesses as previously described with respect to the buried region 108. The portion 8124 may have thicknesses in a range from 1.5 to 10 times thicker than the portions 8182 and 8186. In a particular embodiment, the thickness of the portion 8184 can be in a range from 50 nm to 900 nm thick.

The channel layer 206 can be deposited to form the primary surface 207 such that the primary surface 207 is substantially planar. In an embodiment, the thickness of a portion of the channel layer 206 over the portion 8184 can be in a range from 20 nm to 95 nm. The thickness of the channel layer 206 at locations laterally spaced apart from the buried regions 508 and 818 can be any of the thicknesses of the channel layer 106 as previously described with respect to FIG. 1. The lateral spacing 822 between the portion 8186 of the buried region 818 and the buried region 808 can have any of the values as previously described with respect to the lateral spacing 222.

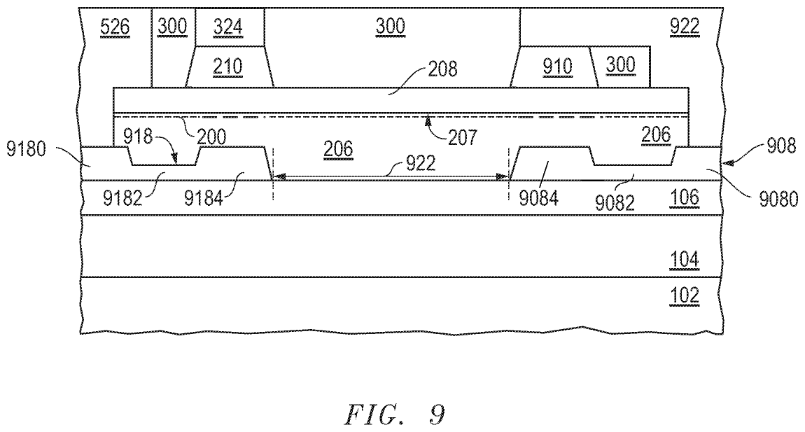

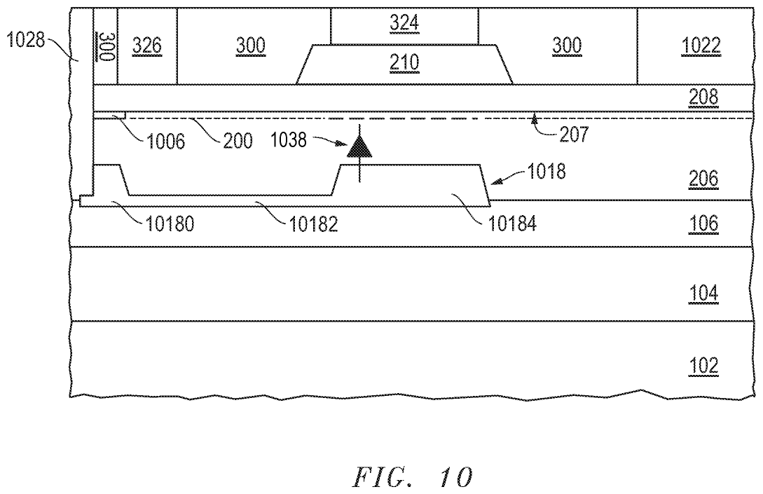

FIG. 9 includes an embodiment that includes a reverse blocking eHEMT. The right-hand portion of the structure is similar to a gated diode. The structure includes a p-type semiconductor member 910 over the barrier layer 108, and the p-type semiconductor member 910 can include any of the compositions, thicknesses, and be formed using any of the techniques as previously described with respect to the gate electrode 210. The structure further includes a drain-side buried region 908 and a source-side buried region 918. The drain-side buried region 908 includes relatively thicker portions 9080 and 9084 and a relatively thinner portion 9082 between the portions 9080 and 9084, and the source-side buried region 918 includes relatively thicker portions 9180 and 9184 and a relatively thinner portion 9182 between the portions 9180 and 9184. The portion 9084 underlies the p-type semiconductor member 910, and the portion 9184 underlies the gate electrode 210 and a relatively thinner portion 9182 between the portions 9180 and 9184.

The portions 9082 and 9182 may have thicknesses as previously described with respect to the buried region 108. The portions 9080, 9084, 9180, and 9184 may have thicknesses in a range from 1.5 to 10 times thicker than the portions 9082 and 9182. The channel layer 206 can have the thickness consideration as previously described with respect to FIG. 8. The lateral spacing 922 between the portion 9184 of the buried region 918 and the portion 9084 of the buried region 908 can have any of the values as previously described with respect to the lateral spacing 222.

The drain electrode 922 is similar to the drain electrode 322 and further includes a portion that contacts the p-type-semiconductor member 910. Although not illustrated in the embodiment of FIG. 9, the buried region 918 can include a portion that extends laterally past the gate electrode towards the drain electrode 922, similar the portion 8186 of the buried region 818 in FIG. 8.

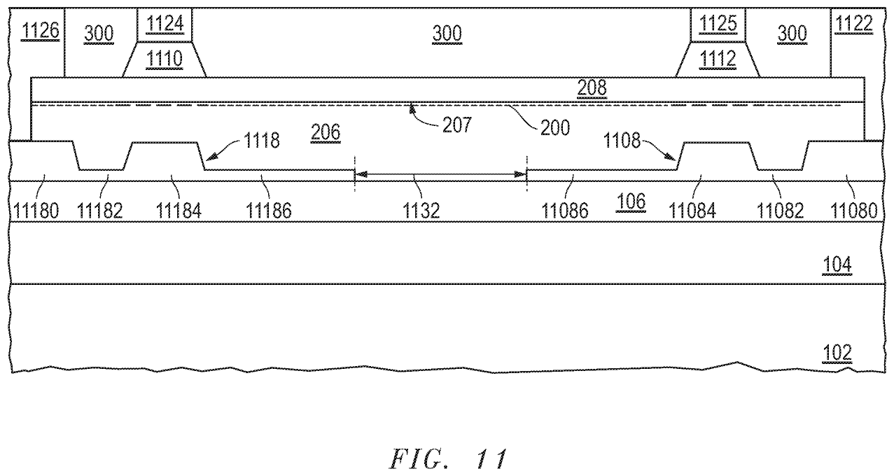

FIG. 10 includes another embodiment in which a buried region 1018 is contacted by a back barrier electrode 1028. The buried region 1018 includes portions 10180, 10182, and 10184 that have thicknesses as previously described with respect to the portions 9180, 9182, and 9184 of the buried region 918. The configuration allows the buried region 1018 to be controlled independently of the source electrode 326, the gate electrode 324, or both. A implanted region 1006 may be formed within the channel layer 206 between the back barrier electrode 1028 and the 2DEG 200 under the source electrode 326, so that the 2DEG 200 does not extend to the back barrier electrode 1028. The implant destroys the lattice and hence kills the 2DEG, effectively isolating the material. Typical implant species are Nitrogen, Argon, Boron, Iron etc. Implant doses range from 1×10¹¹/cm² to 1×10¹⁵/cm². The implantation depth is such that the implanted species cover the depth of the 2DEG, i.e., deeper than the thickness of layer 208.

A diode 1028 lies between the portion 10184 of the buried region 1018 and the 2DEG 200, where the portion 10184 is the anode, and the 2DEG 200 is the cathode. A positive potential on the portion 10184 (anode) helps to lower the energy of the conduction band (Ec) and lowers Rdson until the diode 1028 becomes forward biased, when holes are injected from the portion 10184 into the channel layer 206 that modules the electron density within the 2DEG 200 under the gate electrode 324. A negative potential on the portion 10184 (anode) helps to increase Ec and increase the threshold voltage (Vth).

The HEMT may be used a high-side transistor or a low-side transistor in a switching circuit, where the source of the high-side transistor and the drain of the low-side transistor are coupled at a node and supply power to a load or other similar application. Table 1 includes a list of states and voltages. In the tables, VBB is the voltage on the back barrier electrode 1028, and Vth is the threshold voltage of the HEMT.

TABLE 1
Operating States of HEMT in FIG. 10

| State | VBB | Vth | Comments |
|---|---|---|---|
| Off | Negative | High | Lowers off-state current |
| On | Positive | Low | Lowers Rdson |
| LS Off → On | Negative | High | Lower Qgd/Qgs |
| HS 3^{rd} Q → On | | | (less Miller charge ratio |
| | | | during turn-on) |
| 3^{rd} Q | Positive | Low | Reduces dead-time loss |

In the off-state, a negative voltage for VBB increases the Vth (High Vth in Table 1) of the HEMT and reduces the electron density within the 2DEG 200 under the gate electrode 324 to help keep the off-state current lower than it would have been in the absence of the buried region 1018 and back barrier electrode 1028. In the on-state, a positive voltage for VBB decreases the Vth (Low Vth in Table 1) of the HEMT and allows the Rdson to be lower than it would have been in the absence of the buried region 1018 and the back barrier electrode 1028. During switching operations, a negative voltage VBB and high Vth can help to lower the ratio of gate-to-drain charge divided by the gate-to-source charge. This configuration can be useful when the HEMT is the low-side transistor when switching from the off-state to the on-state, and when the HEMT is the high-side transistor when switching from 3Q operation to the on-state. During 3Q operation, a positive VBB and a low Vth can help to reduce dead-time loss.

In FIG. 10, a drain electrode 1022 is similar to the source electrode 326, and a buried region does not underlie the drain electrode 1022. In another embodiment, the drain-side buried region 108 and drain electrode 322 may be used in conjunction with the buried region 1018 and the back barrier electrode 1028. The lateral spacing between the drain-side buried region and the buried region 1018 can have any of the values as previously described with respect to the lateral spacing 222.

FIG. 11 includes an illustration of a HEMT configured as a bidirectional transistor with buried regions. The HEMT includes a drain/source electrode 1122 that overlies and contacts a buried region 1108, a source/drain electrode 1126 that overlies and contacts a buried region 1118, a gate electrode 1110 and its corresponding gate interconnect 1124, and another gate electrode 1112 and its corresponding gate interconnect. As can be seen in FIG. 11, the right-hand side of the HEMT is a mirror image of the left-hand side of the HEMT. The buried region 1108 includes portions 11080, 11082, 11084, and 11086, and the buried region 1118 includes portions 11180, 11182, 11184, and 11186. The compositions and thicknesses of the buried regions 1108 and 1118 and their corresponding portions can be any of the compositions and thicknesses as previously described with respect to the buried region 818 in FIG. 8. The lateral spacing 1132 can have any of the values as previously described with respect to the lateral spacing 222. As previously described with respect to another embodiment, the channel layer 206 can be formed such that the primary surface 207 is planar.

Other embodiments can be used without deviating from the concepts as described herein. In an embodiment, portions of any of the drain and source electrodes and the gate interconnect (overlying the gate electrode 324) may or may not have portions that act as field plates. A drain-side buried region can help reduce the need for a field plate for the drain electrode, and the source-side buried can help reduce the need for a field plate for either or both of the source electrode and the gate interconnect. In another embodiment, a field plate and a buried region may both be used along the drain-side or the source-side of the HEMT structure. In a further embodiment, the buried regions 818, 918, and 1018 can have an underlying conductive region similar to the conductive region 618 as illustrated in FIGS. 6 and 7. In another embodiment, the gate electrode 210 and gate interconnect 324 can be replaced by a gate dielectric layer and a gate electrode. In another embodiment, the source and gate electrodes can be electrically connected to each other, so that the HEMT structure is a gated diode.

Embodiments as described herein can help to form an enhancement-mode HEMT with a buried region that has better performance than an enhancement-mode HEMT without any buried region. In some embodiments, a diode lies between the buried region and a 2DEG, where the buried region is the anode of the diode. In an off-state, the diode can be forward biased and injects holes into the channel layer to recombine with trapped electrons and reduce or eliminate dynamic on-state resistance. The lateral spacing can be selected so that holes are injected along all of the channel layer that is laterally between the gate electrode and the drain electrode. Further, when in an off-state, a drain-side buried region can lower the maximum electrical field at the drain edge and in the drain region. A drain-side field plate may or may not be used with the drain-side buried region. The drain-side buried region or combination of drain-side field plate and drain-side buried region can be optimized and engineered to achieve a desired electrical field. In an on-state, a buried region at a positive potential with respect to the 2DEG can increase the electron density within the 2DEG and reduce Rdson.

A source-side buried region can be coupled to a source electrode or a back barrier electrode. A relatively thicker portion of the source-side buried region under a gate electrode can help with dual depletion of the channel of the HEMT structure, and a relatively thinner portion of the source-side buried region is relatively farther away from the 2DEG as compared the thicker portion. The relatively farther distance between the thinner portion of the source-side buried region and the 2DEG increases the 2DEG electron density. The thicker portion can be replaced by another relative thinner portion (the source-side buried region may have a substantially uniform thickness similar to the thinner portion) that can be beneficial for 3Q operation. A portion of the source-side buried region may extend beyond the gate electrode to help shield the 2DEG from the substrate voltage.

When the source-side buried region is coupled to a back barrier electrode, further control of the HEMT can be realized. Such a configuration may be useful when the HEMT is a high-side transistor or a low-side transistor in a switching circuit. The back barrier electrode may be at a positive potential that decreases Vth of the HEMT or may be at a negative potential that increases Vth of the HEMT. In the off-state, off-state current can be lowered, and in the on-state, Rdson can be lowered, as compared to a HEMT without the source-side buried and a back barrier electrode. The configuration can help lower the ratio of Qgd/Qgs and reduce dead-time losses during switching and 3Q operations.

Many different aspects and embodiments are possible. Some of those aspects and embodiments are described below. After reading this specification, skilled artisans will appreciate that those aspects and embodiments are only illustrative and do not limit the scope of the present invention. Embodiments may be in accordance with any one or more of the items as listed below.

### Embodiment 1

An electronic device can include a high electron mobility transistor including a first buried region; a channel layer overlying the first buried region; a gate electrode; and a drain electrode overlying the first buried region. The first buried region can extend toward and does not underlie the gate electrode.

### Embodiment 2

The electronic device of Embodiment 1, wherein the first buried region includes a p-type semiconductor material.

### Embodiment 3

The electronic device of Embodiment 2, wherein the channel layer and the first buried region have a same base semiconductor material.

### Embodiment 4

The electronic device of Embodiment 1, wherein the channel layer has a thickness of at least 110 nm over the first buried region.

### Embodiment 5

The electronic device of Embodiment 1, wherein the high electron mobility transistor further includes a source electrode that includes a field plate that extends over and beyond the gate electrode toward the drain electrode.

### Embodiment 6

The electronic device of Embodiment 1, wherein the high electron mobility transistor further includes a source electrode and a second buried region underlying the source electrode.

### Embodiment 7

The electronic device of Embodiment 6, wherein the gate and source electrodes are electrically connected to each other.

### Embodiment 8

The electronic device of Embodiment 6, wherein the high electron mobility transistor is a bidirectional transistor, the drain electrode is a drain/source electrode for the bidirectional transistor, and the source electrode is a source/drain electrode for the bidirectional transistor.

### Embodiment 9

The electronic device of Embodiment 6, wherein the second buried region underlies the channel layer and the gate electrode, extends beyond the gate electrode, and is spaced apart from the first buried region.

### Embodiment 10

The electronic device of Embodiment 6, wherein the first and second buried regions have a same composition.

### Embodiment 11

The electronic device of Embodiment 6, wherein the high electron mobility transistor further includes a conductive region that contacts and underlies the second buried region.

### Embodiment 12

The electronic device of Embodiment 6, wherein the second buried region includes a first portion and a second portion, wherein the first portion underlies the gate electrode and is thicker than the second portion, and (1) the source electrode is closer to the second portion than to the first portion, or (2) the drain electrode is closer to the second portion than to the first portion.

### Embodiment 13

The electronic device of Embodiment 12, wherein a portion of the channel layer overlies the first portion of the second buried region, and the portion of the channel layer has a thickness in a range of 20 nm to 95 nm.

### Embodiment 14

The electronic device of Embodiment 1, wherein the high electron mobility transistor further includes a barrier layer overlying the channel layer, wherein a first portion of the drain electrode extends through the barrier layer and contacts the first buried region, and a second portion of the drain electrode extends over and contacts the barrier layer.

### Embodiment 15

The electronic device of Embodiment 1, wherein the high electron mobility transistor further includes a buffer layer, wherein the first buried region overlies a portion, and not all, of the buffer layer.

### Embodiment 16

The electronic device of Embodiment 1, wherein the buffer layer and the channel layer have a same base semiconductor material, and the buffer layer has a higher dopant concentration as compared to the channel layer.

### Embodiment 17

The electronic device of Embodiment 1, where the high electron mobility transistor is an enhancement-mode transistor.

### Embodiment 18

The electronic device of Embodiment 1, wherein a lateral spacing between the first buried region and the gate electrode is:

x≥7.5(y)+0.3,

where,

x is the lateral spacing between the first buried region and the gate electrode, in units of microns, and

y is a rated voltage of the high electron mobility transistor, where the rated voltage is in units of kV.

### Embodiment 19

The electronic device of Embodiment 1, wherein the high electron mobility transistor is an enhancement-mode transistor, the high electron mobility transistor further includes a buffer layer, a source electrode, and a barrier layer, the first buried region includes a p-type semiconductor material, the buffer layer underlies the channel layer, has a same base semiconductor material as the channel layer, and has a higher dopant concentration as compared to the channel layer, the channel layer and the first buried region include AlₓGa₍₁₋ₓ₎N, where 0≤x≤0.1, the first buried region overlies a portion, and not all, of the buffer layer, the barrier layer overlies the channel layer and underlies the gate electrode, wherein the barrier layer includes Al_{y}Ga_{(1-y)}N, where 0<y≤1 and y>x, a first portion of the drain electrode extends through the barrier layer and contacts the first buried region, and a second portion of the drain electrode extends over and contacts the barrier layer, and the source electrode overlies and contacts the barrier layer and is spaced apart from the channel layer.

### Embodiment 20

An electronic device can include a high electron mobility transistor including a first buried region; a channel layer overlying the first buried region; a gate electrode overlying the channel layer; a p-type semiconductor member overlying the channel layer; and a drain electrode, the first buried region, and the p-type semiconductor member are connected to one another at a node. The p-type semiconductor member is disposed between the gate and drain electrodes.

### Embodiment 21

The electronic device of Embodiment 20, where the first buried region includes a first portion and a second portion, wherein the first portion is thicker than the second portion, and the drain electrode is closer to the second portion than to the first portion.

### Embodiment 22

The electronic device of Embodiment 20, wherein the high electron mobility transistor further includes a source electrode and a second buried region, wherein the source electrode overlies and contacts the second buried region.

### Embodiment 23

The electronic device of Embodiment 22, wherein the second buried region includes a first portion and a second portion, the first portion of the second buried region is thicker than the second portion of the second buried region, and the source electrode is closer to the second portion of the second buried region than to the first portion of the second buried region.

Note that not all of the activities described above in the general description or the examples are required, that a portion of a specific activity may not be required, and that one or more further activities may be performed in addition to those described. Still further, the order in which activities are listed is not necessarily the order in which they are performed.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims.

The specification and illustrations of the embodiments described herein are intended to provide a general understanding of the structure of the various embodiments. The specification and illustrations are not intended to serve as an exhaustive and comprehensive description of all of the elements and features of apparatus and systems that use the structures or methods described herein. Separate embodiments may also be provided in combination in a single embodiment, and conversely, various features that are, for brevity, described in the context of a single embodiment, may also be provided separately or in any subcombination. Further, reference to values stated in ranges includes each and every value within that range. Many other embodiments may be apparent to skilled artisans only after reading this specification. Other embodiments may be used and derived from the disclosure, such that a structural substitution, logical substitution, or another change may be made without departing from the scope of the disclosure. Accordingly, the disclosure is to be regarded as illustrative rather than restrictive.

1. An electronic device comprising:
a high electron mobility transistor including:
a first buried region,
a channel layer overlying the first buried region,
a gate electrode, and
a drain electrode extending through the channel layer and contacting the first buried region,
wherein the first buried region extends toward and is laterally spaced apart from the gate electrode.

2. The electronic device of claim 1, wherein the first buried region includes a p-type semiconductor material.

3. The electronic device of claim 1, wherein the channel layer has a thickness of at least 110 nm over the first buried region.

4. The electronic device of claim 1, wherein the high electron mobility transistor further comprises a source electrode that includes a field plate that extends over and beyond the gate electrode toward the drain electrode.

5. The electronic device of claim 1, wherein the high electron mobility transistor further comprises a source electrode and a second buried region underlying the source electrode.

6. The electronic device of claim 5, wherein the source electrode and the second buried region are electrically connected to each other.

7. The electronic device of claim 5, wherein:
the high electron mobility transistor is a bidirectional transistor,
the drain electrode is a drain/source electrode for the bidirectional transistor, and
the source electrode is a source/drain electrode for the bidirectional transistor.

8. The electronic device of claim 5, wherein the second buried region underlies the channel layer and the gate electrode, extends beyond the gate electrode, and is spaced apart from the first buried region.

9. The electronic device of claim 5, wherein the high electron mobility transistor further comprises a conductive region that contacts and underlies the second buried region.

10. The electronic device of claim 5, wherein the second buried region includes a first portion and a second portion, wherein the first portion underlies the gate electrode and is thicker than the second portion, and the source electrode is closer to the second portion than to the first portion.

11. The electronic device of claim 10, wherein a portion of the channel layer overlies the first portion of the second buried region, and the portion of the channel layer has a thickness in a range of 20 nm to 95 nm.

12. The electronic device of claim 1, wherein the high electron mobility transistor further includes a barrier layer overlying the channel layer, wherein a first portion of the drain electrode extends through the barrier layer and contacts the first buried region, and a second portion of the drain electrode extends over and contacts the barrier layer.

13. The electronic device of claim 1, wherein the high electron mobility transistor further comprises a buffer layer, wherein:
the first buried region overlies a portion, and not all, of the buffer layer,
the buffer layer and the channel layer have a same base semiconductor material, and
the buffer layer has a higher dopant concentration as compared to the channel layer.

14. The electronic device of claim 1, where the high electron mobility transistor is an enhancement-mode transistor.

15. The electronic device of claim 1, wherein a lateral spacing between the first buried region and the gate electrode is:
y≥7.5(x)+0.3,
where,
y is the lateral spacing between the first buried region and the gate electrode, in units of microns, and
x is a rated voltage of the high electron mobility transistor, where the rated voltage is in units of kV, wherein the rated voltage is in a range from 0.1 kV to 1.3 kV.

16. The electronic device of claim 1, wherein:
the high electron mobility transistor is an enhancement-mode transistor,
the high electron mobility transistor further comprises a buffer layer, a source electrode, and a barrier layer,
the first buried region includes a p-type semiconductor material, wherein the p-type semiconductor material includes include Al_{z}Ga_{(1-z)}N, where 0≤z≤0.1,
the buffer layer underlies the channel layer, has a same base semiconductor material as the channel layer, and has a higher dopant concentration as compared to the channel layer,
the channel layer includes AlₓGa₍₁₋ₓ₎N, where 0≤x≤0.1,
the first buried region overlies a portion, and not all, of the buffer layer,
the barrier layer overlies the channel layer and underlies the gate electrode, wherein the barrier layer includes Al_{y}Ga_{(1-y)}N, where 0<y≤1, and wherein y>x,
a first portion of the drain electrode extends through the barrier layer and contacts the first buried region, and a second portion of the drain electrode extends over and contacts the barrier layer, and
the source electrode overlies and contacts the barrier layer.

17-20. (canceled)

21. The electronic device of claim 1, wherein the first buried region has a thinner portion, wherein the thinner portion has a thickness in a range from 5 nm to 500 nm.

22. The electronic device of claim 1, wherein:
the first buried region includes a first portion and a second portion,
the drain electrode contacts the first portion of the first buried region,
the channel layer has a first thickness over the first portion of the first buried region and a second thickness over the second portion of the first buried region, and
the first thickness is thinner than the second thickness.

23. The electronic device of claim 5, wherein the second buried region is spaced apart from the first buried region.

24. The electronic device of claim 5, wherein:
the second buried region includes a first portion and a second portion, and
the channel layer has a first thickness in a range from 20 nm to 95 nm over the first portion of the second buried region has a second thickness of at least 110 nm over the second portion of the second buried region.
